(19) United States
(12) Patent Application Publication
(10) Pub. No.: US 2014/0118938 A1
(43) Pub. Date: May 1, 2014

(54) ELECTRONIC DEVICE HAVING FANS

(71) Applicant: TAI-WEI LIN, New Taipei (TW)

(72) Inventor: TAI-WEI LIN, New Taipei (TW)

(21) Appl. No.: 13/685,511

(22) Filed: Nov. 26, 2012

(30) Foreign Application Priority Data
Oct. 25, 2012 (TW) 101139584

(51) Int. Cl. H05K 7/20

(52) U.S. Cl. CPC H05K 7/20172
USPC 361/695

(57) ABSTRACT

An electronic device includes a chassis, a number of fans arranged in the chassis, a fan bracket, and two locking members. The chassis includes a base and a cover. The base includes a bottom wall supporting the fans and two sidewalls extending from two opposite sides of the bottom. A block extends from each sidewall and aligns with the fans. The cover defines an opening aligned with the fans. The fan bracket includes a covering plate and two mounting plates extending down from a bottom of the covering plate. The fans are sandwiched between the mounting plates. Two cutouts are defined in opposite ends of the covering plate. The locking members are inserted in the corresponding cutouts, to be locked to the blocks of the corresponding sidewalls.

### BACKGROUND

1. Technical Field

The present disclosure relates to an electronic device including a plurality of fans.

2. Description of Related Art

An electronic device often uses a plurality of fans for heat dissipation. The fans are installed in a chassis of the electronic device. However, should a fan need to be repaired or replaced, the cover of the chassis must be removed, which is inconvenient.

### BRIEF DESCRIPTION OF THE DRAWINGS

Many aspects of the present embodiments can be better understood with reference to the following drawings. The components in the drawing are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an electronic device in accordance with an exemplary embodiment, wherein the electronic device includes a fan bracket and two locking members.

FIG. 2 is an enlarged view of the fan bracket and the locking members of FIG. 1.

FIG. 3 is an assembled view of FIG. 1.

FIG. 4 is a cross-sectional view taken along the line IV-IV of FIG. 3.

### DETAILED DESCRIPTION

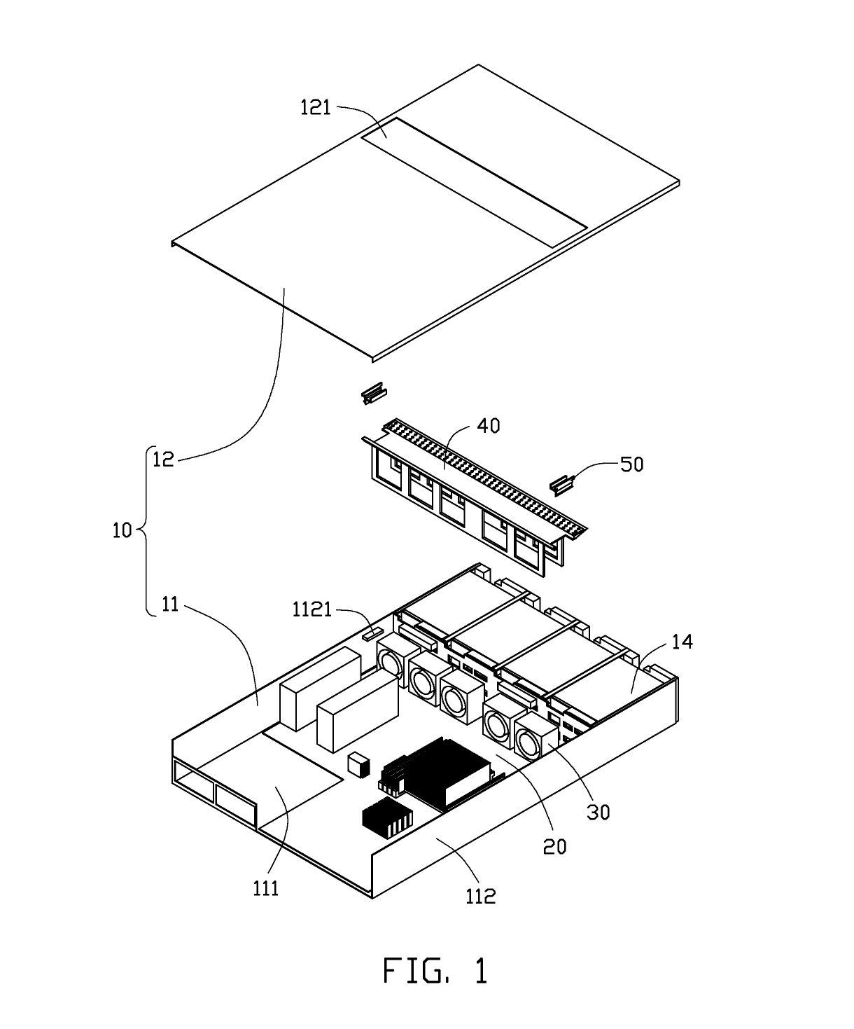

Referring to FIG. 1, an embodiment of an electronic device includes a chassis 10, a motherboard 20 fixed in the chassis 10, a plurality of fans 30, a fan bracket 40, and two resilient locking members 50.

The chassis 10 includes a base 11 and a cover 12. The base 11 includes a bottom wall 111, and two sidewalls 112 extending up from two opposite sides of the bottom wall 111. The motherboard 20 is supported on one end of the bottom wall 111. A function module area 14, for receiving function modules such as data storage devices, is arranged on the bottom wall 111 opposite to the motherboard 20. The fans 30 are set in a row perpendicular to the sidewalls 12, on the bottom wall 111 between the motherboard 20 and the function module area 14, and electronically connected to the motherboard 20. The cover 12 covers the base 11, and encloses the motherboard 20, the fans 30, and the function modules. The cover 12 defines an opening 121 aligned with the fans 30. A block 1121 extends from an inner surface of each sidewall 112 and aligns with the fans 30.

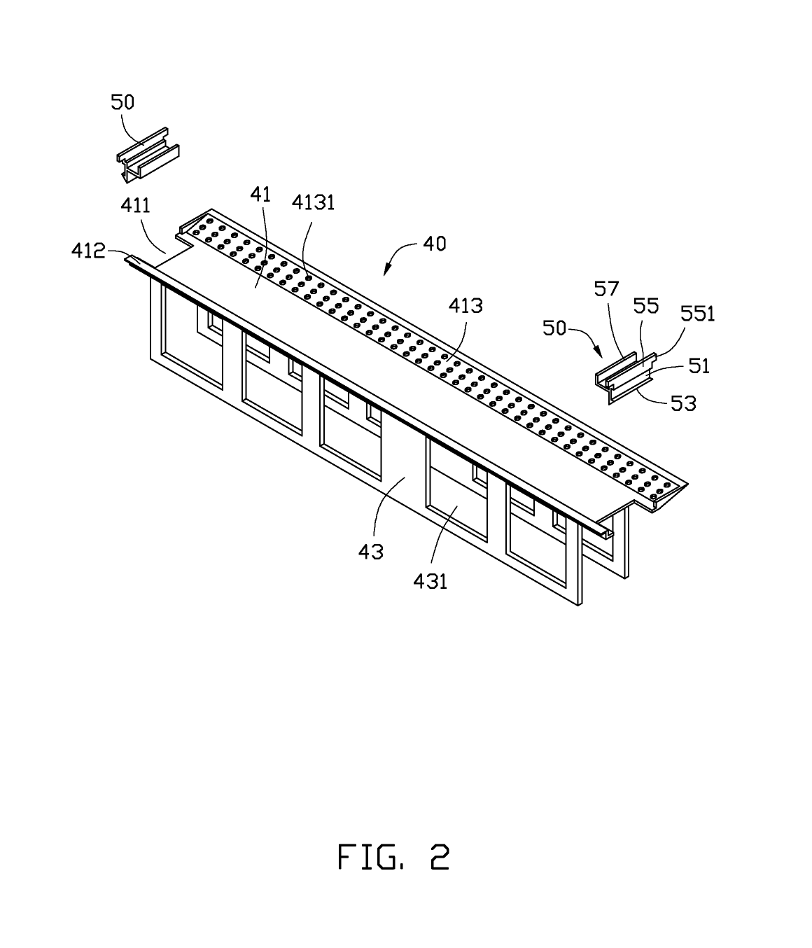

Referring to FIG. 2, the fan bracket 40 includes a covering plate 41 and two parallel mounting plates 43 extending down from opposite sides of a bottom of the covering plate 41. Two rectangular cutouts 411 are defined in opposite ends of the covering plate 41. An L-shaped engaging piece 412 extends up and out from a first side of the covering plate 41. A guiding plate 413 extends up slantingly from a second side of the covering plate 41 opposite to the first side. The guiding plate 413 defines a plurality of through holes 4131. The mounting plates 43 each define a plurality of vents 431.

Each locking member 50 includes a main plate 51, a wedge-shaped locking portion 53 extending from a bottom of a first surface of the main plate 51, an L-shaped pressing plate 55 extending from a top of the first surface of the main plate 51, and an L-shaped operation portion 57 extending from a second surface of the main plate 51 opposite to the pressing plate 55. Two pressing blocks 551 are formed from opposite ends of the pressing plate 55.

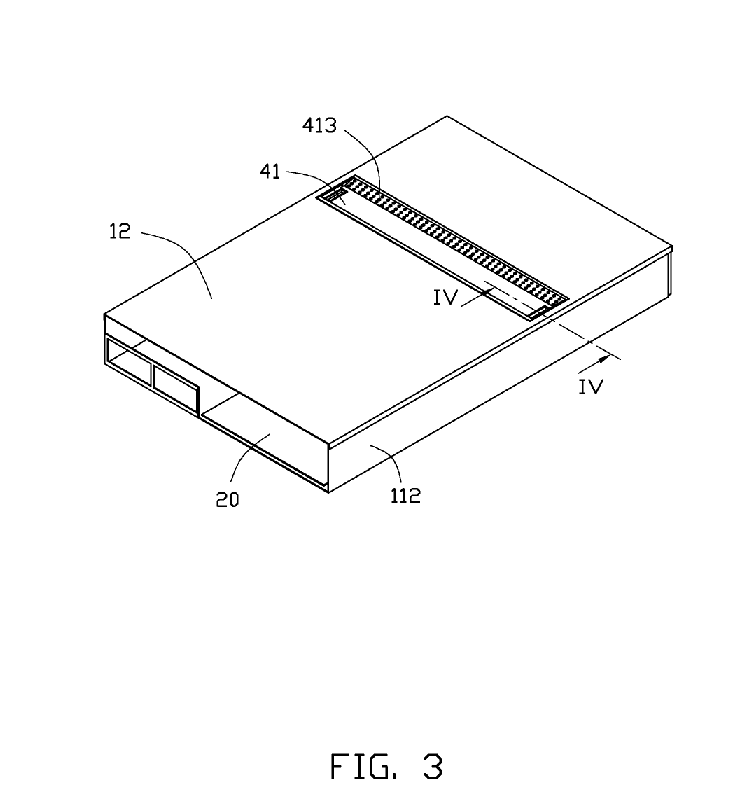

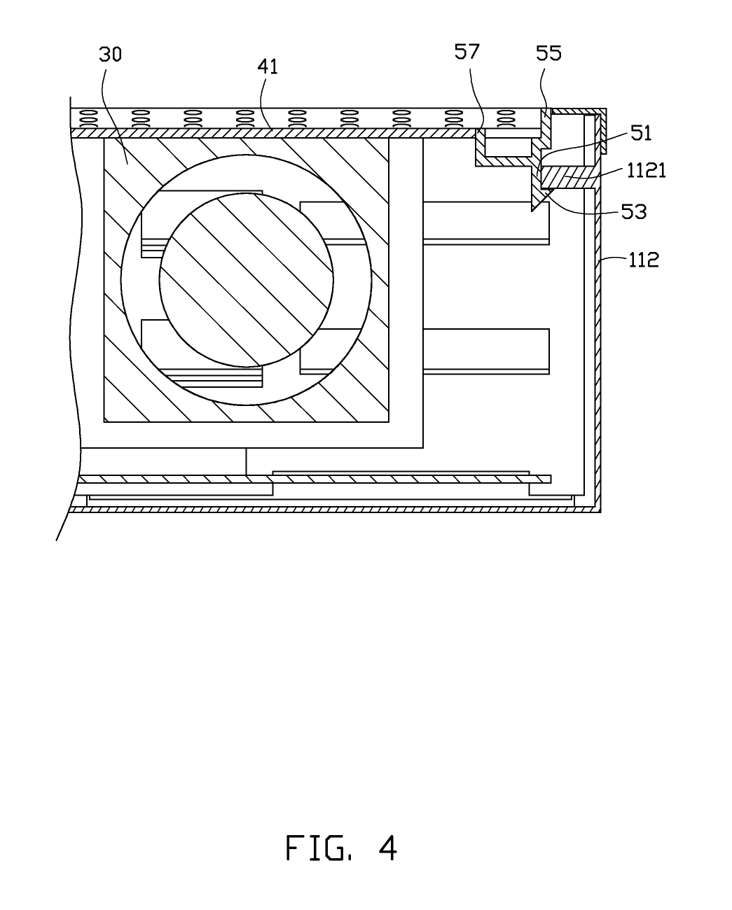

Referring to FIG. 3 and FIG. 4, the cover 12 is mounted on the base 11. The fans 30 align with the opening 121. The fan bracket 40 is inserted in the chassis 10 through the opening 121. The fans 30 are sandwiched between the mounting plates 43, respectively aligned with the vents 431. The engaging piece 412 abuts against a top surface of the cover 12 at a side of the opening 121. The guiding plate 413 abuts against the cover 12 at an opposite side of the opening 121. The locking portions 53 are respectively inserted into the cutouts 411. The locking members 50 are pressed down until the locking portions 53 are respectively locked to the blocks 1121. The pressing blocks 551 abut against the top surface of the covering plate 41 at opposite sides of the corresponding cutouts 411. The operation portions 57 abut against sidewalls bounding the corresponding cutouts 411. Therefore, the fan bracket 40 is locked to the chassis 10 by the locking members 50. The covering plate 41 covers the opening 121. When the fans 30 operate, air is drawn by the fans 30 to flow through the function module area 14 to the motherboard 20. The guiding plate 413 can also guide air to enter the chassis 10 through the through holes 4131.

To repair or replace one or more of the fans 30, the operation portions 57 are pressed toward each other to deform or pull the main plates 51 away from the corresponding sidewalls 112, until the locking portions 53 are released from the corresponding blocks 1121. Thus, the locking members 50 and the fan bracket 40 can be taken out to expose the fans 30, thereby allowing convenient and easy removal and installation of the fans 30.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An electronic device, comprising:
a chassis comprising a base and a cover covering on the base, wherein the base comprises a bottom wall, two sidewalls extending from opposite sides of the bottom wall, the cover defines an opening, a block extends from an inner surface of each sidewall and aligns with the opening;
a plurality of fans arranged on the bottom wall and aligning with the opening;
a fan bracket comprising a covering plate and two mounting plates extending down from the covering plate, the covering plate defining two cutouts in opposite ends of the covering plate respectively adjacent to the sidewalls, wherein the fans are sandwiched between the mounting plates in response to the fan bracket being inserted into the chassis through the opening; and
two locking members each being inserted between a corresponding one of the two cutouts and the corresponding one of the sidewalls, and engaged with the corresponding block.

2. The electronic device as claimed in claim 1, wherein each locking member comprises a main plate, a locking portion extending from a bottom of a first surface of the main plate facing the corresponding sidewall, a pressing plate extending from a top of the first surface of the main plate, and an operation portion extending from a second surface of the main plate opposite to the pressing plate, two pressing blocks are formed from opposite ends of the pressing plate, the locking portion is inserted in the corresponding cutout to engage with the corresponding block, the pressing plate abuts against a top surface of the covering plate adjacent to the corresponding cutout, the operation portion abuts against a sidewall bounding the corresponding cutout.

3. The electronic device as claimed in claim 1, wherein a motherboard is set on the bottom wall, the fans are electronically connected to the motherboard.

4. The electronic device as claimed in claim 3, wherein a function module area is arranged on the bottom wall opposite to the motherboard, the fans are set in a row perpendicular to the sidewalls on the bottom wall, between the motherboard and the function module area.

5. The electronic device as claimed in claim 1, wherein an L-shaped engaging piece extends up and out from a first side of the covering plate, the engaging piece abuts against a top surface of the cover at a side of the opening.

6. The electronic device as claimed in claim 5, wherein a guiding plate extends up slantingly from a second side of the covering plate opposite to the first side, the guiding plate defines a plurality of through holes.
